(19) United States
(12) Patent Application Publication
(10) Pub. No.: US 2026/0114276 A1
(43) Pub. Date: Apr. 23, 2026

(54) HEAT DISSIPATION MEMBER, HEAT DISSIPATION MEMBER MANUFACTURING METHOD, PACKAGE, AND SUBSTRATE

(71) Applicants: NGK ELECTRONICS DEVICES, INC., Mine-shi (JP); NGK INSULATORS, LTD., Nagoya-shi (JP)

(72) Inventor: Hiroshi KOUNO, Ichinomiya-shi (JP)

(21) Appl. No.: 19/424,336

(22) Filed: Dec. 18, 2025

Related U.S. Application Data
(63) Continuation of application No. PCT/JP2024/020823, filed on Jun. 7, 2024.

(30) Foreign Application Priority Data
Jun. 19, 2023 (WO) PCT/JP2023/022631

(51) Int. Cl. H10W 40/25; H10W 40/00; H10W 40/20; H10W 76/18; H10W 90/00

(52) U.S. Cl. CPC H10W 40/255; H10W 40/033; H10W 40/233; H10W 76/18; H10W 90/757

(57) ABSTRACT

A heat dissipating member includes: a sintered material portion containing copper and at least one of tungsten and molybdenum; and a plurality of silicon oxide particles dispersed in the sintered material portion. The heat dissipating member has a copper content of M_{Cu} weight percent, a tungsten content of M_{W} weight percent, a molybdenum content of M_{Mo} weight percent, and a silicon oxide content of M_{SiO2} weight percent in terms of SiO₂ equivalent, relative to a total weight of copper, tungsten, and molybdenum. The heat dissipating member satisfies: 0.9≥M_{Cu}/(M_{Cu}+M_{W}+M_{Mo})≥0.045; and 0.01≥M_{SiO2}/(M_{Cu}+M_{W}+M_{Mo})≥0.0003.

### CROSS-REFERENCE TO RELATED APPLICATION

This application is a continuation application of PCT/JP2024/020823, filed on Jun. 7, 2024, which claims the benefit of priority of International Patent Application No. PCT/JP2023/022631, filed on Jun. 19, 2023, the entire contents of which are incorporated herein by reference.

### BACKGROUND

### Technical Field

The present disclosure relates to a heat dissipating member, a heat dissipating member manufacturing method, a package, and a substrate.

### Description of the Background Art

A heat dissipating member is sometimes used to promote heat dissipation from a semiconductor device operating at a relatively large current, such as a power semiconductor element. The heat dissipating member is sometimes used while being joined to a member (hereinafter also referred to as a different material member) formed of a different material from the heat dissipating member.

For example, a package disclosed in Japanese Patent Application Laid-Open No. 2015-204426 includes a heat sink plate (the heat dissipating member) and a ceramic frame (the different material member). The heat sink plate is for dissipating heat generated from an electronic component mounted to an upper surface thereof. The ceramic frame is joined to the heat sink plate to surround a site where the electronic component is mounted. They are joined by brazing. A brazing temperature is approximately 780° C. The ceramic frame is formed of alumina or aluminum nitride, for example.

The above-mentioned heat sink plate is a metal plate. As the metal plate, a metal plate having high thermal conductivity and capable of mitigating warpage of the package caused by a difference in coefficient of linear expansion from the ceramic frame during brazing is selected. For example, a composite metal plate or a clad metal plate is used. The composite metal plate is formed by impregnation, for example. Specifically, it is formed by impregnating a porous refractory metal plate with copper (Cu). Refractory metal, such as tungsten (W) and molybdenum (Mo), has a close coefficient of linear expansion to ceramics, so that the heat sink plate can have a close coefficient of linear expansion to the ceramic frame. Cu has excellent thermal conductivity, so that the heat sink plate can have high heat dissipating performance.

When the heat sink plate is required to have a close coefficient of linear expansion to the ceramic frame, the composite metal plate or the clad metal plate is widely used as described above. When a match between coefficients of linear expansion is not important, a simple metal material is widely used, and thermal conductively can significantly be increased by using pure copper, for example.

In the above, some features related to the patent documents, namely, Japanese Patent Application Laid-Open No. 2015-204426, have been outlined.

When the package is exposed to a heat cycle, thermal stress is applied to a junction between the heat dissipating member and the different material member due to a difference in thermal expansion between the heat dissipating member and the different material member. As a result, the junction or the different material member might be damaged (typically cracked). According to technology disclosed in Japanese Patent Application Laid-Open No. 2015-204426 described above, the difference in thermal expansion between the heat sink plate (heat dissipating member) and the ceramic frame (different material member) can be relatively small but cannot completely be reduced to zero. Furthermore, W and Mo have high rigidity, so that, when a W or Mo content of the heat dissipating member is increased to suppress the difference in thermal expansion, the heat dissipating member has a high Young's modulus, and, as a result, an effect of mitigating thermal stress by elastic deformation of the heat dissipating member tends to be reduced. The difference in thermal expansion is thus more likely to lead directly to damage of the junction or the different material member in this case. While there are many materials having low Young's moduli, a suitable material has not yet been found when not-excessive thermal expansion and good thermal conductivity are taken into account.

### SUMMARY

The present disclosure has been conceived to solve a problem as described above, and it is one object of the present disclosure to provide a heat dissipating member capable of suppressing reduction in reliability of a junction or a different material member to be joined caused by a difference in thermal expansion from the different material member while having a close coefficient of thermal expansion to a ceramic material and good thermal conduction.

Aspect 1 is a heat dissipating member including: a sintered material portion containing copper and at least one of tungsten and molybdenum; and a plurality of silicon oxide particles dispersed in the sintered material portion, wherein the heat dissipating member has a copper content of M_{Cu} weight percent, a tungsten content of M_{W} weight percent, a molybdenum content of M_{Mo} weight percent, and a silicon oxide content of M_{SiO2} weight percent in terms of SiO₂ equivalent, relative to a total weight of copper, tungsten, and molybdenum, the heat dissipating member satisfying: 0.9≥M_{Cu}/(M_{Cu}+M_{W}+M_{Mo})≥0.045; and 0.01≥M_{SiO2}/(M_{Cu}+M_{W}+M_{Mo})≥0.0003.

Aspect 2 is the heat dissipating member according to Aspect 1, wherein in particle size distribution based on the number of particles in a particle size range of the plurality of silicon oxide particles of 0.2 μm or more and less than 10 μm, a percentage of a particle size range of 0.2 μm or more and less than 1.0 μm is 70% or more.

Aspect 3 is the heat dissipating member according to Aspect 2, wherein the plurality of silicon oxide particles each have a particle size of less than 10 μm.

Aspect 4 is the heat dissipating member according to Aspect 1, wherein in particle size distribution based on the number of particles in a particle size range of the plurality of silicon oxide particles of 0.2 μm or more and less than 5 μm, a percentage of a particle size range of 0.2 μm or more and less than 1.0 μm is 70% or more.

Aspect 5 is the heat dissipating member according to Aspect 4, wherein the plurality of silicon oxide particles each have a particle size of less than 5 μm.

Aspect 6 is the heat dissipating member according to Aspect 1, wherein in particle size distribution based on the number of particles in a particle size range of the plurality of silicon oxide particles of 0.2 μm or more and less than 3 μm, a percentage of a particle size range of 0.2 μm or more and less than 1.0 μm is 70% or more.

Aspect 7 is the heat dissipating member according to Aspect 6, wherein the plurality of silicon oxide particles each have a particle size of less than 3 μm.

Aspect 8 is the heat dissipating member according to Aspect 1, wherein in particle size distribution based on the number of particles in a particle size range of the plurality of silicon oxide particles of 0.2 μm or more and less than 2 μm, a percentage of a particle size range of 0.2 μm or more and less than 1.0 μm is 70% or more.

Aspect 9 is the heat dissipating member according to Aspect 8, wherein the plurality of silicon oxide particles each have a particle size of less than 2 μm.

Aspect 10 is the heat dissipating member according to any one of Aspects 1 to 9, the heat dissipating member satisfying 0.80≥M_{Cu}/(M_{Cu}+M_{W}+M_{Mo})≥0.15.

Aspect 11 is the heat dissipating member according to any one of Aspects 1 to 10, wherein a remainder of the heat dissipating member other than copper, tungsten, molybdenum, and silicon oxide accounts for less than 0.5 weight percent relative to the total weight.

Aspect 12 is the heat dissipating member according to any one of Aspects 1 to 11, the heat dissipating member satisfying: M_{Mo}=0; and 0.806≥M_{Cu}/(M_{Cu}+M_{W})≥0.075.

Aspect 13 is the heat dissipating member according to any one of Aspects 1 to 11, the heat dissipating member satisfying: M_{W}=0; and 0.887≥M_{Cu}/(M_{Cu}+M_{Mo})≥0.133.

Aspect 14 is a heat dissipating member manufacturing method for manufacturing the heat dissipating member according to any one of Aspects 1 to 13, the heat dissipating member manufacturing method including: mixing at least one of tungsten powder having an average particle size of 0.5 μm or more and 10 μm or less and molybdenum powder having an average particle size of 0.5 μm or more and 10 μm or less, copper powder having an average particle size of 1.5 μm or more and 5.0 μm or less, and SiO₂ powder having an average particle size of 7 nm or more and 200 nm or less to form mixed powder, the mixed powder having a copper content of M_{Cu(P)} weight percent, a tungsten content of M_{W(P)} weight percent, a molybdenum content of M_{Mo(P)} weight percent, and a silicon oxide content of M_{SiO2(P)} weight percent in terms of SiO₂ equivalent, relative to a total weight of copper, tungsten, and molybdenum, the mixed powder satisfying 0.9≥M_{Cu(P)}/(M_{Cu(P)}+M_{W(P)}+M_{Mo(P)})≥0.045, and 0.03≥M_{SiO2(P)}/(M_{Cu(P)}+M_{W(P)}+M_{Mo(P)})≥0.001; and heating the mixed powder to a temperature at or above a melting point of copper.

Aspect 15 is the heat dissipating member manufacturing method according to Aspect 14, further including forming at least one green sheet containing the mixed powder and a resin, wherein the heating of the mixed powder is performed by firing the at least one green sheet.

Aspect 16 is the heat dissipating member manufacturing method according to Aspect 15, wherein the at least one green sheet includes a plurality of green sheets, the manufacturing method further including laminating the plurality of green sheets to form a laminated body, and wherein the heating of the mixed powder is performed by firing the laminated body.

Aspect 17 is a package including: the heat dissipating member according to any one of Aspects 1 to 13; and a ceramic frame, wherein the heat dissipating member has a heat dissipating surface and a main surface opposite the heat dissipating surface, and the ceramic frame is disposed on the main surface of the heat dissipating member and has an inner surface surrounding a cavity and an outer surface opposite the inner surface.

Aspect 18 is a substrate including: the heat dissipating member according to any one of Aspects 1 to 13; and a ceramic insulating layer, wherein the heat dissipating member has a heat dissipating surface and a main surface opposite the heat dissipating surface, and the ceramic insulating layer is disposed on the main surface of the heat dissipating member.

According to Aspect 1 described above, the heat dissipating member tends to obtain good thermal conduction characteristics as a result of containing copper and enables adjustment of a coefficient of thermal expansion as a result of containing at least one of tungsten and molybdenum. In addition, a Young's modulus can be suppressed by containing the silicon oxide particles, while a large negative impact on thermal conduction characteristics can be avoided by keeping the amount of silicon oxide not excessive. Accordingly, reduction in reliability of a junction or a different material member to be joined to the heat dissipating member caused by a difference in thermal expansion from the different material member can be suppressed while the heat dissipating member has not-excessive thermal expansion and good thermal conduction.

These and other objects, features, aspects and advantages of the present disclosure will become more apparent from the following detailed description when taken in conjunction with the accompanying drawings.

### BRIEF DESCRIPTION OF DRAWINGS

FIG. 1 is a schematic perspective view showing a configuration of a semiconductor module according to Embodiment 1 with a portion thereof omitted so that the interior of a cavity is visible.

FIG. 2 is a schematic cross-sectional view of the semiconductor module taken along the line II-II of FIG. 1.

FIG. 3 is a schematic cross-sectional view showing a configuration of a package as a component of the semiconductor module of FIG. 2.

FIG. 4 is a flowchart schematically showing a method of manufacturing the package according to Embodiment 1.

FIG. 5 is a schematic partial cross-sectional view showing one step of the method of manufacturing the package according to Embodiment 1.

FIG. 6 is an enlarged view of a portion of FIG. 5.

FIG. 7 is a schematic partial cross-sectional view showing one step of the method of manufacturing the package according to Embodiment 1.

FIG. 8 is a schematic partial cross-sectional view showing one step of the method of manufacturing the package according to Embodiment 1.

FIG. 9 is a schematic cross-sectional view showing a configuration of a semiconductor module according to Embodiment 2.

FIG. 10 is an electron micrograph of a cross section of a heat dissipating member in Example 2.

FIG. 11 is an electron micrograph of a cross section of a heat dissipating member in Example 3.

FIG. 12 is an electron micrograph of a cross section of a heat dissipating member in Example 9.

FIG. 13A is a graph showing a relation between a copper content and stress at a strain of 1% of a heat dissipating member containing copper and tungsten.

FIG. 13B is a graph showing a relation between a copper content and stress at a strain of 1% of a heat dissipating member containing copper and molybdenum.

FIG. 14A is a graph showing a relation between a coefficient of thermal expansion and stress at a strain of 1% of the heat dissipating member containing copper and tungsten.

FIG. 14B is a graph showing a relation between a coefficient of thermal expansion and stress at a strain of 1% of the heat dissipating member containing copper and molybdenum.

FIG. 15 is a diagram schematically showing a fine structure of a heat dissipating member in which silicon oxide particles are not dispersed.

FIG. 16 is a diagram schematically showing a fine structure of a heat dissipating member in which silicon oxide particles are dispersed.

FIG. 17 is a schematic cross-sectional view showing a configuration of a semiconductor module according to Embodiment 4 FIG. 18 is a schematic cross-sectional view showing a configuration of a heat dissipating substrate as a component of the semiconductor module of FIG. 17.

FIG. 19 is a schematic partial cross-sectional view showing one step of a method of manufacturing the heat dissipating substrate according to Embodiment 4.

### DESCRIPTION OF THE PREFERRED EMBODIMENTS

Embodiments of the present disclosure will be described below with reference to the drawings.

### Embodiment 1

### (Configuration of Semiconductor Module)

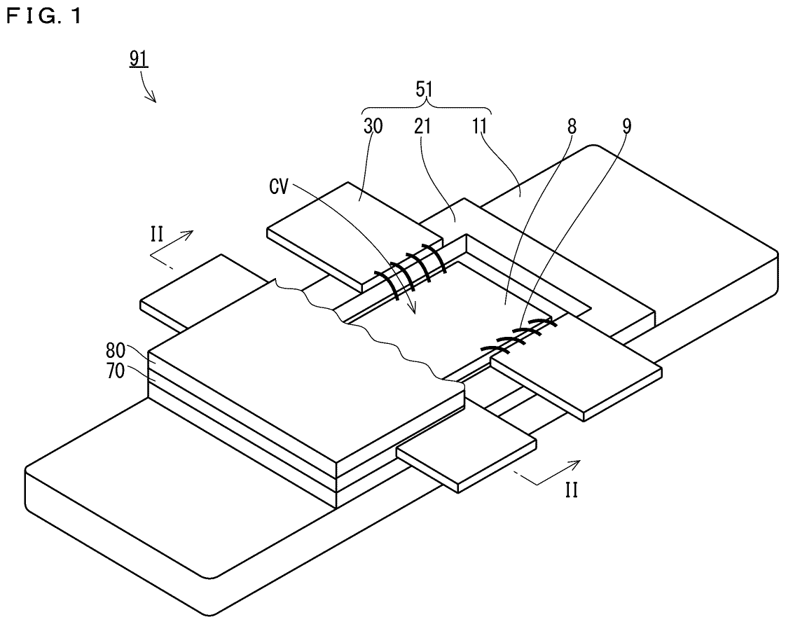

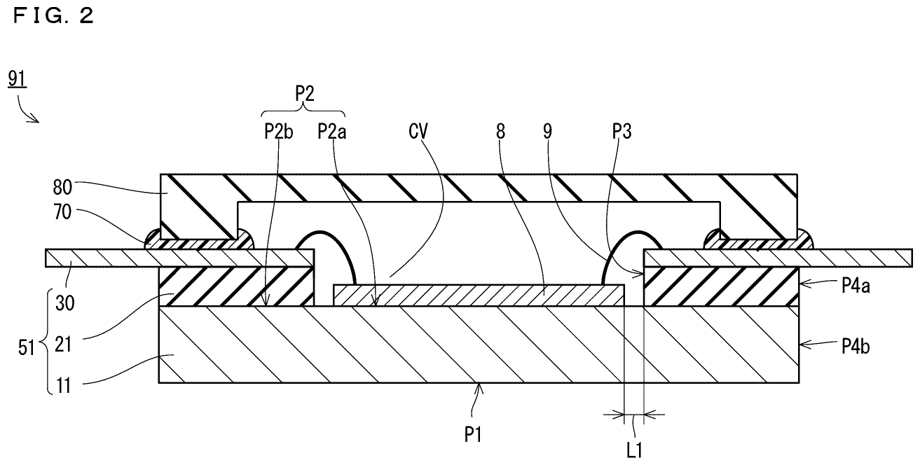

FIG. 1 is a schematic perspective view showing a configuration of a semiconductor module 91 according to Embodiment 1. FIG. 2 is a schematic cross-sectional view of the semiconductor module 91 taken along the line II-II of FIG. 1. The semiconductor module 91 includes a package 51 and a semiconductor element 8. The semiconductor module 91 may include wires 9 as wiring members for the semiconductor element 8. The semiconductor module 91 may include a lid 80 for sealing a cavity CV. The lid 80 may be attached to the package 51 by an adhesive layer 70. Portions of the lid 80 and the adhesive layer 70 are not illustrated in FIG. 1, so that the interior of the cavity CV of the package 51 is partially visible.

The semiconductor element 8 is typically a power semiconductor element, and, in this case, the semiconductor module 91 is a power module. The power semiconductor element may be for radio frequency (RF), and, in this case, the semiconductor module 91 is a RF power module. The semiconductor element 8 is not limited to the power semiconductor element and may be large-scale integration (LSI) operating at high power or an integrated circuit (IC), for example. While one semiconductor element 8 is illustrated in each of FIGS. 1 and 2, a plurality of semiconductor elements 8 may be mounted to the package 51. An element other than the semiconductor element 8, such as a passive element, may also be mounted.

### (Configuration of Package)

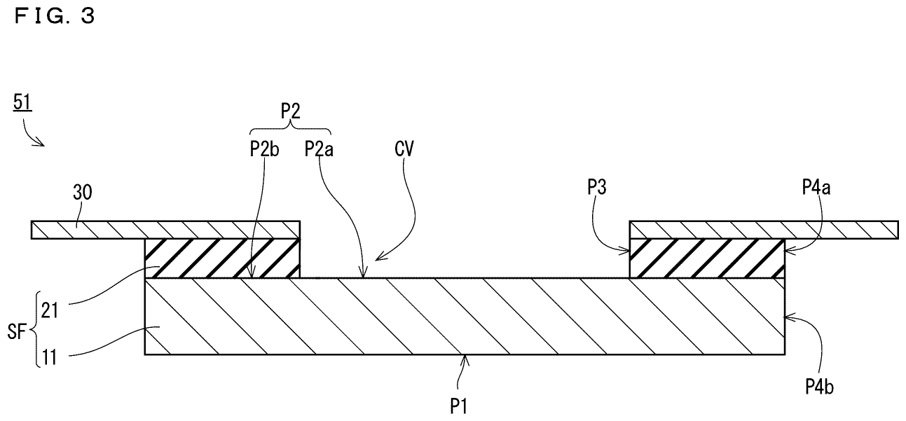

FIG. 3 is a schematic cross-sectional view showing a configuration of the package 51 as a component of the semiconductor module 91 (FIG. 2). At a point in time when the package 51 is prepared for manufacture of the semiconductor module 91, the semiconductor element 8 may not yet be mounted as illustrated in FIG. 3. The package 51 has the cavity CV to be sealed with the lid 80. The package 51 includes a heat dissipating plate 11 (heat dissipating member) and a ceramic frame 21.

The heat dissipating plate 11 has a heat dissipating surface P1 and a main surface P2 opposite the heat dissipating surface P1. The heat dissipating surface P1 of the heat dissipating plate 11 is to be typically attached to a support member (not illustrated). The support member is a mounting board or a heat dissipating member, for example. The heat dissipating plate 11 may have a penetrating portion (not illustrated) through which a fastener (e.g., screw) for attachment to the support member passes.

The ceramic frame 21 is a frame formed of ceramics. Use of the ceramic frame 21 as a frame of the package 51 can increase thermal resistance and insulation of the package 51. A material for the ceramic frame 21 may contain alumina as a major component and may contain a trace amount of silica to promote sintering of the ceramic frame 21.

The ceramic frame 21 is disposed on the main surface P2 of the heat dissipating plate 11. The ceramic frame 21 has an inner surface P3 surrounding the cavity CV and an outer surface P4a opposite the inner surface P3. The heat dissipating plate 11 may have a side surface P4b flush with the outer surface P4a of the ceramic frame 21. An outer edge of the ceramic frame 21 may have a rectangular shape as illustrated in FIG. 1 in an in-plane direction perpendicular to a thickness direction. Each side of the rectangular shape has a length of 4 mm or more and 40 mm or less, for example. The ceramic frame 21 has a thickness of 0.1 mm or more and 1 mm or less, for example.

In Embodiment 1, the main surface P2 of the heat dissipating plate 11 includes a cavity surface P2a facing the cavity CV and a joined surface P2b joined directly to the ceramic frame 21. The ceramic frame 21 and the heat dissipating plate 11 are thus directly joined to each other. An expression “directly joined” herein means that a component other than a component derived from the heat dissipating plate 11 and the ceramic frame 21 is not detected at the junction.

The package 51 may include a lead frame 30 (metal terminal). The lead frame 30 is disposed on the ceramic frame 21 and is separated from the heat dissipating plate 11 by the ceramic frame 21. The lead frame 30 forms an electrical path connecting the interior and the exterior of the cavity CV. Between the lead frame 30 and the ceramic frame 21, a joining material (not illustrated) for joining them to each other may be disposed. The joining material may be formed by Ag sintering, for example, and, in this case, the above-mentioned joining material is a mixture of a thermosetting resin (e.g., an epoxy resin or a silicon resin) and Ag particles. A silver braze may be used for the joining material. In this case, a metallization layer for the silver braze is typically formed on the ceramic frame 21 in advance.

As one example of a method of forming the metallization layer, a paste to be the metallization layer is first printed on a green sheet to be the ceramic frame 21 before a firing step for forming the ceramic frame 21 and the heat dissipating plate 11 (described in detail below). Specifically, metal powder of at least any one of W, Mo, and Cu, an additive, a resin, a solvent, and the like are first mixed, and further ceramic powder is added as necessary and kneaded to prepare the paste. The paste is printed to the green sheet prepared in the preceding step by screen printing, for example. After printing, the green sheet is dried under conditions at a temperature of 110° C. and for five minutes, for example. Alternatively, the metallization layer may be formed by laminating a green sheet containing metal on the green sheet to be the ceramic frame 21 before the firing step for forming the ceramic frame 21 and the heat dissipating plate 11 (described in detail below).

The lid 80 (FIGS. 1 and 2) may be formed of ceramics, and the ceramics may contain alumina as a major component and are substantially alumina. Alternatively, the lid 80 may contain a resin. The resin is a liquid crystal polymer, for example. Inorganic fillers may be dispersed in the resin, and the inorganic fillers are silica particles, for example. Dispersion of the inorganic fillers in the resin can increase strength and durability of the lid 80.

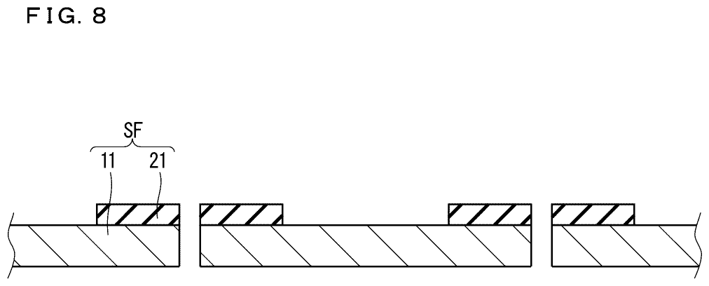

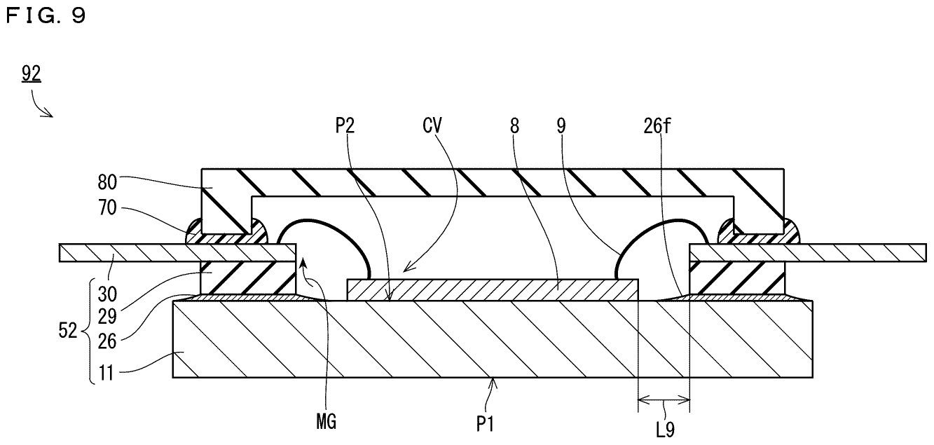

The semiconductor element 8 (FIG. 2) is to be mounted to the cavity surface P2a (FIG. 3) of the main surface P2 of the heat dissipating plate 11 of the package 51. A distance L1 (FIG. 2) between the mounted semiconductor element 8 and the inner surface P3 of the ceramic frame 21 may be 25 μm or less. The distance L1 may be zero. In other words, the semiconductor element 8 and the inner surface P3 of the ceramic frame 21 may be in contact with each other. As described above, the distance L1 is easily reduced compared with a distance L9 (FIG. 9: Embodiment 2). This is because the semiconductor element 8 and a brazing material layer 26 do not interfere with each other. The brazing material layer 26 has fluidity when being formed and flows inward of an inner peripheral surface (a surface facing the cavity CV) of a ceramic frame 29 as illustrated in FIG. 9. A portion of the brazing material layer 26 having flowed inside the cavity CV forms a fillet 26f at an edge of the cavity CV. A flow distance, that is, a width dimension of the fillet 26f is likely to be greater than 25 μm. To sufficiently reduce the possibility of interference between the fillet 26f and the semiconductor element 8, the distance L9 (FIG. 9) between the semiconductor element 8 and the inner surface of the ceramic frame 29 is required to be greater than 25 μm. As a result of such need for large spacing between the semiconductor element 8 and ceramic frame 29, a footprint (an area of a region in which the semiconductor element 8 is mountable) in the cavity CV is reduced. Furthermore, lengths of the wires 9 are increased, typically leading to deterioration of electrical characteristics, such as an unintentional increase in inductance.

The semiconductor element 8 may be mounted using a solder material (not illustrated), for example. After mounting of the semiconductor element 8, the wires 9 (FIG. 2) may be formed to electrically connect the semiconductor element 8 to the lead frame 30. They may be formed by wire bonding. The lid 80 may then be attached to the package 51. It may be attached using the adhesive layer 70. The adhesive layer 70 may be a thermosetting resin. The adhesive layer 70 is disposed on the ceramic frame 21 to surround the cavity CV. The adhesive layer 70 may include a portion disposed on the ceramic frame 21 via the lead frame 30 as illustrated in FIG. 2. The adhesive layer 70 has a thickness between the lid 80 and the package 51 of 100 μm or more and 360 μm or less, for example.

In Embodiment 1, the ceramic frame 21 and the heat dissipating plate 11 as a whole are formed as one fired body SF. The ceramic frame 21 and the heat dissipating plate 11 are thus directly joined to each other. Thus, between the ceramic frame 21 and the heat dissipating plate 11, a joining layer (e.g., the brazing material layer 26 (FIG. 9: Embodiment 2)) for joining them is not disposed. An Ag brazing material is typically used as the brazing material layer 26 (FIG. 9: Embodiment 2). When the brazing material layer 26 contains Ag, Ag migration is likely to occur as indicated by an arrow MG (FIG. 9) upon long-term application of a negative potential to the lead frame 30 relative to a potential of the heat dissipating plate 11. Ag migration might cause insufficient electrical insulation between the heat dissipating plate 11 and the lead frame 30. According to Embodiment 1, this phenomenon can be prevented.

### (Material for Heat Dissipating Plate)

The heat dissipating plate 11 is a sintered body including a sintered material portion containing Cu and refractory metal and a plurality of silicon oxide particles dispersed in the sintered material portion. The refractory metal has a higher melting point than Cu. The refractory metal used in the present embodiment is W and/or Mo, that is, at least one of W and Mo. The plurality of silicon oxide particles may be sintered together with the sintered material portion. The sintered material portion may account for a major proportion of the heat dissipating plate 11.

To increase heat dissipating performance of the heat dissipating plate 11, a material for the heat dissipating plate 11 preferably has high thermal conductivity. Such high thermal conductivity is easily obtained when the heat dissipating plate 11 contains a sufficient proportion of Cu. On the other hand, Cu has a higher coefficient of linear expansion than a typical ceramic material (e.g., alumina), so that an excessive Cu content of the heat dissipating plate 11 is likely to cause a problem of a difference in thermal expansion between the heat dissipating plate 11 and the ceramic frame 29.

When the heat dissipating plate 11 contains a sufficient proportion of at least one of W and Mo, the heat dissipating plate 11 can have a closer coefficient of linear expansion to ceramics, such as alumina, compared with a case where the heat dissipating plate contains almost only Cu. The difference in thermal expansion between the heat dissipating plate 11 and the ceramic frame 21 can thus be reduced. On the other hand, when a W or Mo content of the heat dissipating plate 11 is increased, the heat dissipating plate 11 has a high Young's modulus due to high rigidity of W and Mo. As a result, the effect of mitigating thermal stress by elastic deformation of the heat dissipating plate 11 is reduced. The difference in thermal expansion is thus likely to lead to thermal stress at the junction between the heat dissipating plate 11 and the ceramic frame 21 or at the ceramic frame 21 itself. The difference in thermal expansion is thus likely to directly damage the junction between the heat dissipating plate 11 and the ceramic frame 21 or the ceramic frame 21 itself. Suppression of the Young's modulus of the heat dissipating plate 11 is thus desirable. The heat dissipating plate 11 contains silicon oxide for this purpose as will be described in detail below.

The heat dissipating plate 11 contains Cu, at least one of W and Mo, and silicon oxide. The heat dissipating plate 11 has a Cu content of M_{Cu} wt % (weight percent), a W content of M_{W} wt %, and a Mo content of M_{Mo} wt % relative to a total weight of Cu, W, and Mo. An equation M_{Cu} wt %+M_{W} wt %+M_{Mo} wt %=100 wt % thus holds true. Relative to the total weight, a silicon oxide content is M_{SiO2} wt % in terms of SiO₂ equivalent. A specific method of measuring the silicon oxide content of the heat dissipating plate 11 will be described below.

A composition of the heat dissipating plate 11 satisfies the following conditions:

$$0.9 \geq {M}_{Cu} / ( {M}_{Cu} + {M}_{W} + {M}_{Mo} ) \geq 0.0 \; 45 ; and$$

$$0. 01 \geq {M}_{SiO 2} / ( {M}_{Cu} + {M}_{W} + {M}_{Mo} ) \geq 0.0003 .$$

When M_{Cu}/(M_{Cu}+M_{W}+M_{Mo}) is less than 0.045, the heat dissipating plate has poor thermal conductivity. When M_{Cu}/(M_{Cu}+M_{W}+M_{Mo}) is more than 0.9, a coefficient of thermal expansion is less likely to match a coefficient of thermal expansion of another member, such as a frame formed of ceramics and a mounting board, and, as a result, warpage or cracking might occur. When M_{SiO2}/(M_{Cu}+M_{W}+M_{Mo}) is less than 0.0003, a significant effect of suppressing the Young's modulus of the heat dissipating plate 11 cannot be obtained. When M_{SiO2}/(M_{Cu}+M_{W}+M_{Mo}) is more than 0.01, sintered body strength withstanding use as the heat dissipating member cannot be obtained. The following condition may further be satisfied.

$$0.8 \geq {M}_{Cu} / ( {M}_{Cu} + {M}_{W} + {M}_{Mo} ) \geq 0.15$$

The following condition may further be satisfied.

$$0.37 \geq {M}_{Cu} / ( {M}_{Cu} + {M}_{W} + {M}_{Mo} ) \geq 0.10$$

The heat dissipating plate 11 may not necessarily contain Mo and may satisfy the following conditions:

$${M}_{Mo} = 0 ; and$$

$$0.806 \geq {M}_{Cu} / ( {M}_{Cu} + {M}_{W} ) \geq 0.075 .$$

When M_{Cu}/(M_{Cu}+M_{W}) is less than 0.075, the heat dissipating plate is likely to have insufficient thermal conductivity. When M_{Cu}/(M_{Cu}+M_{W}) is more than 0.806, the coefficient of thermal expansion is less likely to match the coefficient of thermal expansion of the other member, such as the frame formed of ceramics and the mounting board, and, as a result, warpage or cracking might occur. The following condition may further be satisfied.

$$0.25 \geq {M}_{Cu} / ( {M}_{Cu} + {M}_{W} ) \geq 0.10$$

Alternatively, the heat dissipating plate 11 may not necessarily contain W and may satisfy the following conditions:

$${M}_{W} = 0 ; and$$

$$0.887 \geq {M}_{Cu} / ( {M}_{Cu} + {M}_{Mo} ) \geq 0.133 .$$

When M_{Cu}/(M_{Cu}+M_{Mo}) is less than 0.133, the heat dissipating plate is likely to have insufficient thermal conductivity. When M_{Cu}/(M_{Cu}+M_{Mo}) is more than 0.887, the coefficient of thermal expansion is less likely to match the coefficient of thermal expansion of the other member, such as the frame formed of ceramics and the mounting board, and, as a result, warpage or cracking might occur. The following condition may further be satisfied.

$$0.37 \geq {M}_{Cu} / ( {M}_{Cu} + {M}_{Mo} ) \geq 0.18$$

A remainder of the heat dissipating plate 11 other than Cu, W, Mo, and silicon oxide may account for less than 0.5 wt % relative to the total weight of Cu, W, and Mo. In other words, the heat dissipating plate 11 may be formed substantially only of Cu, at least one of W and Mo, and silicon oxide.

Since the plurality of silicon oxide particles are dispersed in the heat dissipating plate 11, particle sizes of the silicon oxide particles can be measured by electron microscopy of a cross section of the heat dissipating plate 11. A specific method of measuring the particle sizes will be described below. Particle size distribution obtained by this measurement of the particle sizes may satisfy at least any one of the following first to fourth conditions.

As the first condition, in particle size distribution based on the number of particles in a particle size range of the plurality of silicon oxide particles of 0.2 μm or more and less than 10 μm, a percentage (i.e., a percentage based on the number of particles) of a particle size range of 0.2 μm or more and less than 1.0 μm is 70% or more. In this case, a percentage of silicon oxide particles each having a particle size of 10 μm or more in the plurality of silicon oxide particles is preferably 0.1% or less. In other words, the percentage of the silicon oxide particles each having a particle size of 10 μm or more in the plurality of silicon oxide particles is substantially zero. In other words, the plurality of silicon oxide particles each have a particle size of less than 10 μm. This can further diminish concern that breakage of the heat dissipating plate 11 originates from the silicon oxide particles.

As the second condition, in particle size distribution based on the number of particles in a particle size range of the plurality of silicon oxide particles of 0.2 μm or more and less than 5 μm, a percentage of a particle size range of 0.2 μm or more and less than 1.0 μm is 70% or more. In this case, a percentage of silicon oxide particles each having a particle size of 5 μm or more in the plurality of silicon oxide particles is preferably 0.1% or less. In other words, the percentage of the silicon oxide particles each having a particle size of 5 μm or more in the plurality of silicon oxide particles is substantially zero. In other words, the plurality of silicon oxide particles each have a particle size of less than 5 μm. This can further diminish the concern that breakage of the heat dissipating plate 11 originates from the silicon oxide particles.

As the third condition, in particle size distribution based on the number of particles in a particle size range of the plurality of silicon oxide particles of 0.2 μm or more and less than 3 μm, a percentage of a particle size range of 0.2 μm or more and less than 1.0 μm is 70% or more. In this case, a percentage of silicon oxide particles each having a particle size of 3 μm or more in the plurality of silicon oxide particles is preferably 0.1% or less. In other words, the percentage of the silicon oxide particles each having a particle size of 3 μm or more in the plurality of silicon oxide particles is substantially zero. In other words, the plurality of silicon oxide particles each have a particle size of less than 3 μm. This can further diminish the concern that breakage of the heat dissipating plate 11 originates from the silicon oxide particles.

As the fourth condition, in particle size distribution based on the number of particles in a particle size range of the plurality of silicon oxide particles of 0.2 μm or more and less than 2 μm, a percentage of a particle size range of 0.2 μm or more and less than 1.0 μm is 70% or more. In this case, a percentage of silicon oxide particles each having a particle size of 2 μm or more in the plurality of silicon oxide particles is preferably 0.1% or less. In other words, the percentage of the silicon oxide particles each having a particle size of 2 μm or more in the plurality of silicon oxide particles is substantially zero. In other words, the plurality of silicon oxide particles each have a particle size of less than 2 μm. This can further diminish the concern that breakage of the heat dissipating plate 11 originates from the silicon oxide particles.

### (Method of Measuring Particle Sizes of Silicon Oxide Particles Dispersed in Heat Dissipating Plate)

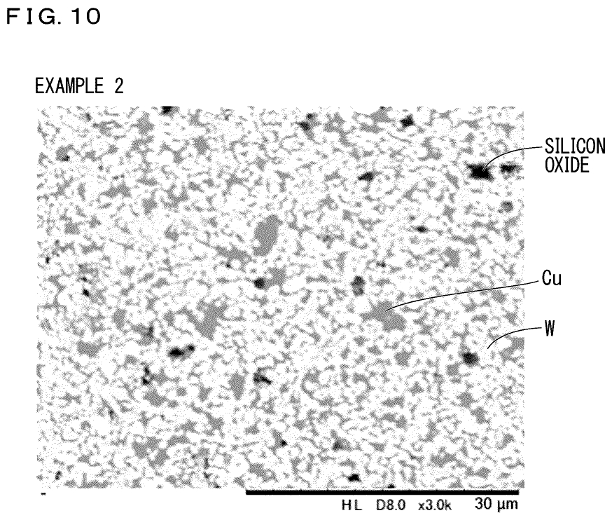

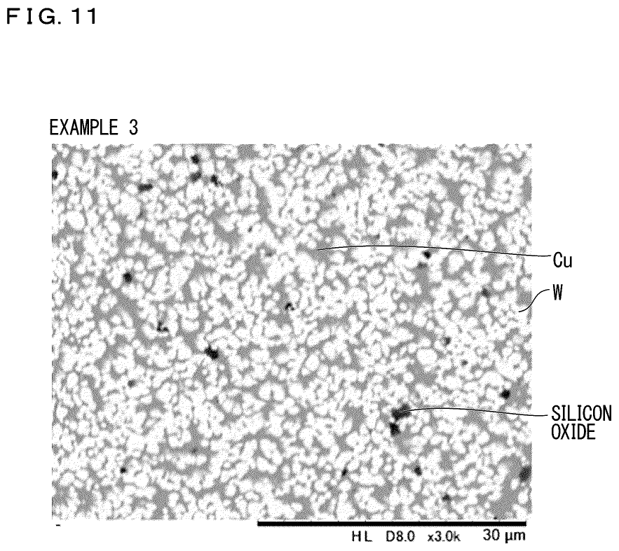

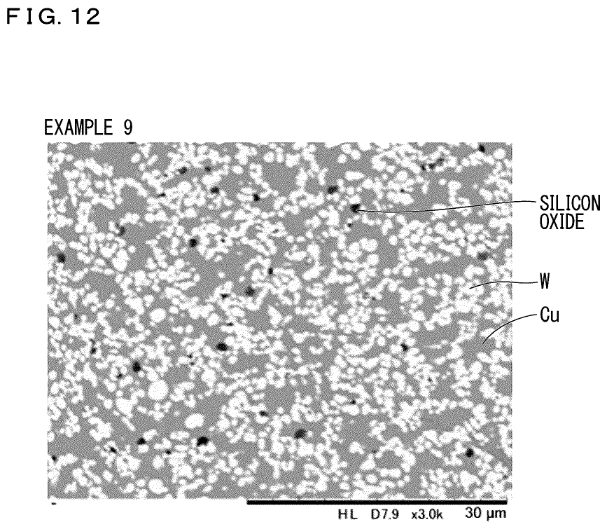

First, the heat dissipating plate 11 is cut along a thickness direction. A cross section of the heat dissipating plate 11 is thus exposed. Ion milling is performed for a region at and near the center of the cross section. An image of the region is captured using an electron microscope. In experiments described below, a field emission electron probe microanalyzer (FE-EPMA, model: JXA-8500F (from JEOL Ltd.)) was used as the electron microscope under conditions at 2000× to 3000× measurement magnification and at an acceleration voltage of 15 kV. As can be seen from FIGS. 10 to 12, in the image, a white portion is the refractory metal (W and/or Mo), a gray portion is Cu, and a black portion is the silicon oxide particles. Data of the image is binarized to black and white using image processing software (ImageJ) so that a region of the silicon oxide particles is distinguished from the other region. The binarized image data includes a plurality of regions corresponding to the silicon oxide particles. Ellipse fitting is performed for each of the regions. Specifically, for each of the regions, an ellipse including therein the region and having a minimum area is determined. An average of a minor axis and a major axis of the ellipse is calculated as a particle size of each of the silicon oxide particles.

### (Method of Measuring Silicon Oxide Content of Heat Dissipating Plate)

Areas of the region of the refractory metal (W and/or Mo), the region of Cu, and the region of the silicon oxide particles are calculated from the above-mentioned image data by binarization to black and white using the image processing software (ImageJ). Ratios of the areas are considered as volume ratios of the refractory metal (W and/or Mo), Cu, and the silicon oxide particles to the heat dissipating plate 11. The volume ratios are divided by densities of the respective materials to calculate weight composition ratios. For example, a density of W of 19.3 g/cm³, a density of Mo of 10.2 g/cm³, a density of Cu of 8.9 g/cm³, and a density of silicon oxide (SiO₂) of 2.2 g/cm³ are used for calculation.

As for the composition ratios of the refractory metal (W and/or Mo) and Cu, when raw material composition ratios are already known, the known composition ratios are preferably used as they are more accurate than composition ratios based on image analysis as described above. The raw material composition ratios are thus used as the composition ratios of the refractory metal (W and/or Mo) and Cu in the heat dissipating plate 11 (heat dissipating member) in the experiments described below.

### (Method of Manufacturing Package)

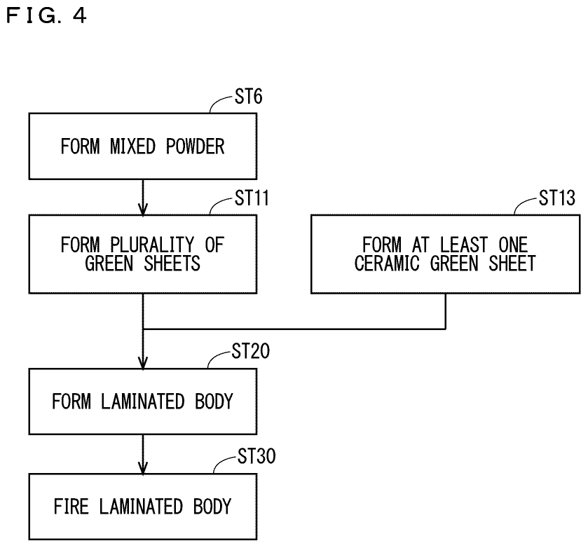

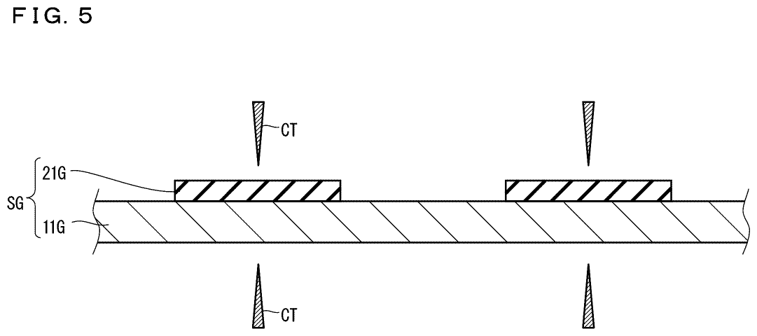

FIG. 4 is a flowchart schematically showing a method of manufacturing the package 51 (FIG. 3). FIGS. 5 to 8 are schematic partial cross-sectional views showing steps of the manufacturing method.

In step ST6 (FIG. 4), at least one of W powder and Mo powder, Cu powder, and SiO₂ powder are mixed to form mixed powder. An average particle size of W powder and Mo powder may be 0.5 μm or more and 10 μm or less, preferably may be 0.5 μm or more and 3 μm or less, and more preferably may be 0.5 μm or more and 1.5 μm or less. An average particle size of W powder and Mo powder of less than 0.5 μm increases costs of raw materials, and an average particle size of W powder and Mo powder of more than 10 μm makes it difficult to obtain a uniform sintered body due to a difference in specific gravity between the raw materials. An average particle size of Cu powder may be 1.5 μm or more and 5.0 μm or less. An average particle size of Cu powder of less than 1.5 μm increases a cost of a raw material. An average particle size of more than 5.0 μm makes it difficult to obtain a uniform sintered body due to a difference in specific gravity between the raw materials. An average particle size of SiO₂ powder may be 7 nm or more and 200 nm or less, preferably may be 7 nm or more and 100 nm or less, and more preferably may be 7 nm or more and 50 nm or less. An average particle size of more than 200 nm makes it difficult to obtain a dense sintered body after sintering. On the other hand, SiO₂ powder having an average particle size of less than 7 nm is difficult to manufacture, so that use of the powder as a raw material significantly increases costs of the raw materials for the heat dissipating plate. While SiO₂ powder may be crystalline or amorphous, amorphous SiO₂ powder is preferable as it is readily available.

The average particle size of SiO₂ powder may be measured using an SEM photograph of SiO₂ powder, ellipse fitting similar to that described above is performed on each of a plurality of particles of SiO₂ powder in an image captured at approximately 50000× magnification using an SEM, and an average of a minor axis and a major axis of an ellipse is calculated as a particle size of the particle. As the average particle size, an average value of particle sizes of 100 particles is used, for example. An average particle size of W powder and Mo powder may be measured by a Fisher's method (Japan Tungsten & Molybdenum Industries Association (JP) standard TMIAS0001:1999 particle size test method). A particle size of Cu powder may be measured by laser diffraction and is measured using a nano particle size distribution measurement device SALD-7500nano (from Shimadzu Corporation) after being agitated in isopropyl alcohol (IPA) for one minute, for example.

The mixed powder has a copper content of M_{Cu(P)} wt %, a tungsten content of M_{W(P)} wt %, a molybdenum content of M_{Mo(P)} wt %, and a silicon oxide content of M_{SiO2(P)} wt % in terms of SiO₂ equivalent, relative to a total weight of Cu, Mo, and W and satisfies:

$$0.9 \geq {M}_{Cu ( P )} / ( {M}_{Cu ( P )} + {M}_{W ( P )} + {M}_{Mo ( P )} ) \geq 0.045 ; and$$

$$0.03 \geq {M}_{SiO 2 ( P )} / ( {M}_{Cu ( P )} + {M}_{W ( P )} + {M}_{Mo ( P )} ) \geq 0.001 .$$

The above-mentioned mixing step may include a first mixing step of mixing Cu powder and SiO₂ powder to obtain Cu—SiO₂ mixed powder and a second mixing step of mixing the Cu—SiO₂ mixed powder and at least one of W powder and Mo powder. In this case, a proportion of SiO₂ powder located on surfaces of particles of Cu powder in the eventually obtained mixed powder can be increased. The above-mentioned mixing step may be performed using a ball mill, for example. After the mixing step, only the mixed powder may be isolated. Isolation, however, is not necessarily required, and the mixed powder as well as a solvent, a disperser, a plasticizer, and the like may form a suspension, for example. The suspension may be a raw material for green sheets or a molded body described below.

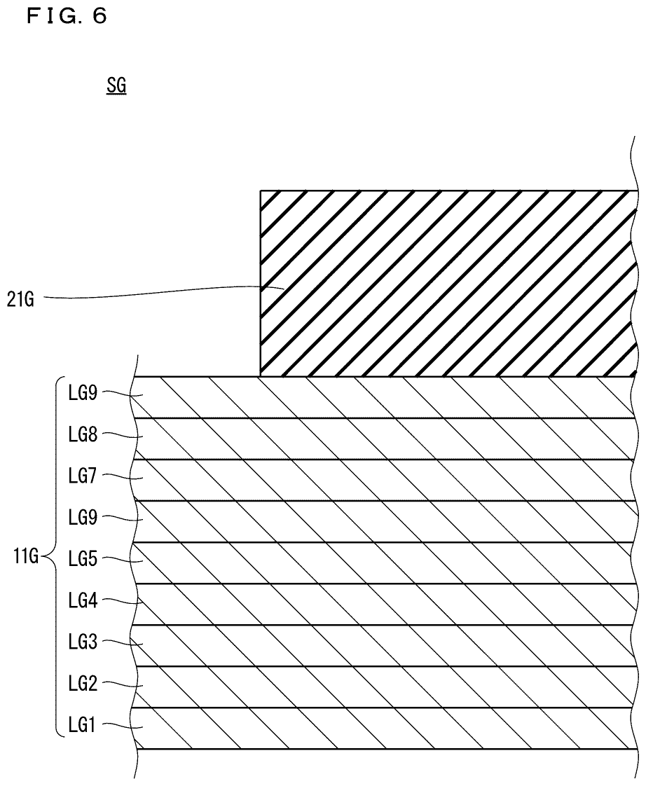

In step ST11 (FIG. 4), a plurality of green sheets LG1 to LG9 (see FIG. 6 described below) to be the heat dissipating plate 11 (FIG. 3) by being fired is formed. While a structure to be the heat dissipating plate 11 by being fired is a laminated body of nine green sheets in FIG. 6, the number of green sheets is not particularly limited. The green sheets LG1 to LG9 contain the mixed powder and a resin. The green sheets LG1 to LG9 may be formed by dividing a single green sheet. As a method of forming the green sheets from the mixed powder, a known typical method may be used. To describe this with an example, a slurry is first prepared. The slurry is obtained by mixing powder to be a component of the sintered body with the resin, the suspension, the solvent, and the like using the ball mill. The slurry is processed into the green sheets by a doctor blade method. Planar shapes of the green sheets are determined according to the shape of a target component. The planar shapes of the green sheets for forming the heat dissipating plate 11 are typically generally rectangular shapes.

In step ST13 (FIG. 4), a frame ceramic green sheet 21G to be the ceramic frame 21 (FIG. 3) by being fired is formed. Examples of powder for forming the frame ceramic green sheet 21G include Al₂O₃ powder as a major component and SiO₂ powder as a sintering aid. A planar shape of the frame ceramic green sheet 21G is a shape of a frame obtained by removing a portion corresponding to the cavity CV (FIG. 3) of the ceramic frame 21. Specifically, the frame ceramic green sheet 21G is formed, after being formed as a simple sheet by a doctor blade method, by removing the portion corresponding to the cavity CV.

In step ST20 (FIG. 4), the green sheets LG1 to LG9 and the frame ceramic green sheet 21G are laminated to form a laminated body SG (FIGS. 5 and 6). The laminated body SG includes a laminated body 11G formed by laminating the green sheets LG1 to LG9. The laminated body 11G is to be the heat dissipating plate 11 (FIG. 3) by being fired.

Next, at a position where breaking described below is performed, a trench (not illustrated) may be formed in a surface of each of the laminated body 11G and the frame ceramic green sheet 21G by machining using cutting edges CT (FIG. 5) and laser processing using a laser processing device (not illustrated).

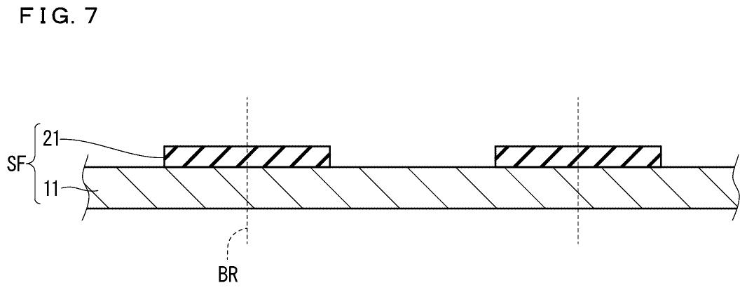

In step ST30 (FIG. 4), the laminated body SG (FIG. 5) is fired. The green sheets LG1 to LG9 and the frame ceramic green sheet 21G are thus fired. The above-mentioned mixed powder is thus fired. Firing changes the laminated body SG into the fired body SF (FIG. 7). A firing temperature is 1100° C. or more and 1400° C. or less, for example. A firing temperature of 1100° C. or more enables heating of the laminated body SG to a temperature at or above a melting point of Cu. In other words, the above-mentioned mixed powder can be heated to the temperature at or above the melting point of Cu. The heat dissipating plate 11 containing Cu can thus be formed with high quality. On the other hand, a firing temperature of 1400° C. or less can avoid a difficulty in a step caused by an excessively high firing temperature.

Next, a breaking step originating from the above-mentioned trench is performed as indicated by dashed lines BR (FIG. 7). As a result, the fired body SF is divided into a plurality of portions. A plurality of fired bodies SF corresponding to a plurality of packages 51 (FIG. 3) are thus obtained (FIG. 8).

Next, the lead frame 30 (FIG. 3) is attached to each of the fired bodies SF. The package 51 (FIG. 3) is thus obtained.

In the above-mentioned manufacturing method, plating may be performed at an appropriate timing after the firing step. The above-mentioned manufacturing method is one example as described above, and various modifications are applicable. For example, cutting may be performed on the laminated body SG before firing instead of performing the breaking step on the fired body SF. While the semiconductor element 8 (FIG. 2) is mounted at a timing after the breaking step according to the above-mentioned manufacturing method, mounting may be performed not at the timing but at a timing after the firing step and before the breaking step.

Since the heat dissipating plate 11 includes the laminated body 11G of the plurality of green sheets in the above-mentioned manufacturing method, the heat dissipating plate 11 having a large thickness can easily be formed by increasing the number of laminated green sheets. On the other hand, as a modification, the heat dissipating plate 11 may include a single green sheet, and, in this case, the manufacturing method is simplified. As another modification, a manufacturing method not including a step of forming any green sheet may be used. For example, a molded body may be formed by press molding of powder instead of forming the green sheet. The molded body as obtained is fired, so that the heat dissipating member can be obtained without forming the green sheet. An additive may be added to the mixed powder to be press molded for the purpose of facilitating press molding. The additive is typically a material substantially disappearing by the end of firing at the latest and is any one of a solvent, a disperser, a plasticizer, and a resin or a combination of any of them, for example.

### Effects

According to the present embodiment, the heat dissipating plate 11 tends to obtain good thermal conduction characteristics as a result of containing Cu and enables adjustment of the coefficient of thermal expansion as a result of containing at least one of W and Mo. In addition, the Young's modulus can be suppressed by containing the silicon oxide particles, while a large negative impact on thermal conduction characteristics can be avoided by keeping the amount of silicon oxide not excessive. From among various materials, such as silicon oxide, alumina, zirconia, and titania, as typical ceramic materials for obtaining a ceramic structure, silicon oxide has a low Young's modulus and a low coefficient of thermal expansion as a material for particles dispersed in the sintered material portion of the heat dissipating plate 11, so that silicon oxide is a preferable material for the purpose of obtaining the above-mentioned effect. While silicon oxide after firing may be crystalline or amorphous, amorphous silicon oxide is more desirable as it has a lower Young's modulus and a lower coefficient of thermal expansion. Accordingly, reduction in reliability of the junction or the ceramic frame 21 (different material member) to be joined to the heat dissipating plate 11 caused by the difference in thermal expansion from the ceramic frame 21 (different material member) can be suppressed while the heat dissipating plate 11 has a close coefficient of thermal expansion to the ceramic material and good thermal conduction.

In particle size distribution of the silicon oxide particles, a percentage of a particle size range of 0.2 μm or more and less than 1.0 μm is preferably 70% or more as described above. According to the inventor's study, an effect of reducing the Young's modulus of the heat dissipating plate 11 is particularly large when the silicon oxide particles each have a particle size in a particle size range of 0.2 μm or more and less than 1.0 μm. Silicon oxide particles having excessively large particle sizes are considered to produce a small effect of reducing the Young's modulus. The silicon oxide particles having excessively large particle sizes rather raise concern that breakage of the heat dissipating plate 11 originates from them.

The heat dissipating plate 11 (FIG. 3) may have the side surface P4b flush with the outer surface P4a of the ceramic frame 21. A portion of the side surface P4b may be a broken surface obtained in the breaking step (FIG. 7). In this case, the footprint (area of a region in which the semiconductor element 8 and the like are mountable) is easily secured while breakage of the package 51 originating from a portion between the outer surface P4a and the side surface P4b is avoided. A typical case in which the side surface P4b is not flush with the outer surface P4a includes a case where the outer surface P4a protrudes outward from the side surface P4b or a case where the outer surface P4a is located inside the side surface P4b. In the former case, breakage might originate from the protrusion. In the latter case, the outer edge of the ceramic frame 21 is located inward, so that an inner edge of the ceramic frame 21 is also located inward as long as a width of the ceramic frame 21 is required to be maintained to a predetermined dimension, and, as a result, the footprint is reduced.

### Embodiment 2

FIG. 9 is a schematic cross-sectional view showing a configuration of a semiconductor module 92 according to Embodiment 2. The semiconductor module 92 has a configuration in which the package 51 of the semiconductor module 91 (FIG. 2: Embodiment 1) has been replaced with a package 52 according to Embodiment 2. The package 52 includes the ceramic frame 29 and the brazing material layer 26 (joining layer) in place of the ceramic frame 21 (FIG. 2: Embodiment 1). The ceramic frame 29 is formed of ceramics, and the ceramics are typically alumina. The brazing material layer 26 is a silver brazing material, for example. A metallization layer (not illustrated) is preferably disposed on a surface of the ceramic frame 29 facing the brazing material layer 26. As the joining layer, a resin adhesive material layer may be used in place of the brazing material layer 26.

### Embodiment 3

The heat dissipating plate 11 (FIG. 3) to which the ceramic frame 21 has not been attached may be prepared. For example, formation of the frame ceramic green sheet 21G (FIG. 5) is omitted in the method of manufacturing the fired body SF (FIG. 7) described above in Embodiment 1, so that the heat dissipating plate 11 to which another member, such as the ceramic frame 21, has not been attached is obtained. Another member may be attached to the heat dissipating plate 11 thus obtained, and the package 52 (FIG. 9: Embodiment 2) can be obtained by attaching the ceramic frame 29 and the like. As a modification, a molded body may be formed by press molding instead of forming any green sheet as described in Embodiment 1.

### Embodiment 4

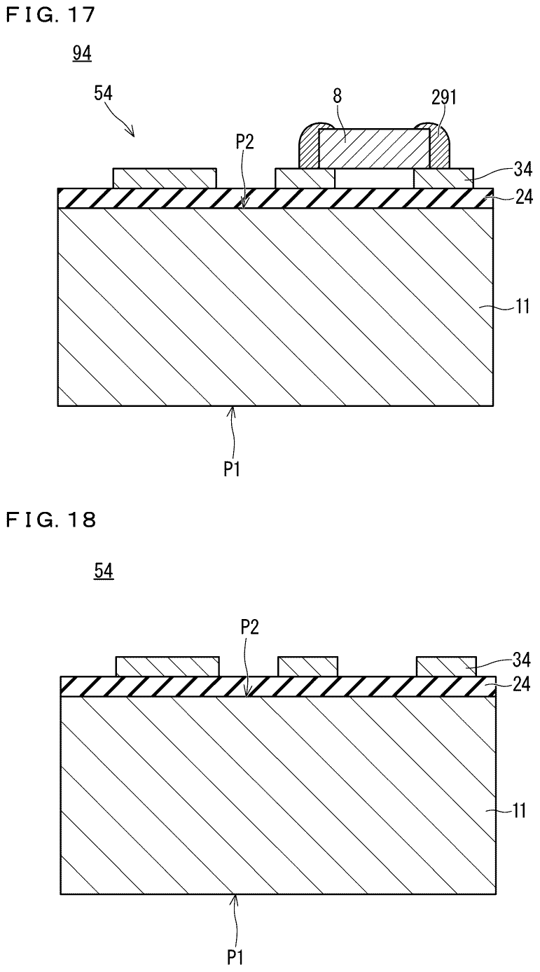

FIG. 17 is a schematic cross-sectional view showing a configuration of a semiconductor module 94 according to Embodiment 4. FIG. 18 is a schematic cross-sectional view showing a configuration of a heat dissipating substrate 54 as a component of the semiconductor module 94 in FIG. 17.

The semiconductor module 94 includes the heat dissipating substrate 54 and the semiconductor element 8 mounted thereto. The heat dissipating substrate 54 includes the heat dissipating plate 11 and a ceramic insulating layer 24 disposed on the main surface P2 of the heat dissipating plate 11. The heat dissipating substrate 54 includes a conductor layer 34 disposed on the ceramic insulating layer 24. The conductor layer 34 is electrically insulated from the heat dissipating plate 11 by the ceramic insulating layer 24. The semiconductor element 8 is mounted to the conductor layer 34. A joining material 291 may be used for mounting. A bonding wire and the like may be joined to the conductor layer 34.

In Embodiment 4, the heat dissipating plate 11 preferably has a thickness of 0.3 mm or more and 3.0 mm or less and more preferably has a thickness of 0.5 mm or more and 1.5 mm or less. An excessively small thickness leads to insufficient mechanical strength of the heat dissipating plate 11. An excessively large thickness leads to an excessively high thermal resistance. The ceramic insulating layer 24 has a smaller thickness than the heat dissipating plate 11. The ceramic insulating layer 24 preferably has a thickness of 5 μm or more and 50 μm or less and more preferably has a thickness of 5 μm or more and 20 μm or less. An excessively small thickness is likely to cause a problem of a variation in thickness of the ceramic insulating layer 24. Specifically, electrical insulation is likely to be insufficient in a portion having a locally small thickness. An excessively large thickness leads to an excessively high thermal resistance. The conductor layer 34 has a smaller thickness than the heat dissipating plate 11. The conductor layer 34 preferably has a thickness of 5 μm or more and 200 μm or less and more preferably has a thickness of 5 μm or more and 20 μm or less. An excessively small thickness is likely to cause a problem of a variation in thickness of the conductor layer 34. An excessively large thickness leads to an excessively high thermal resistance.

The ceramic insulating layer 24 is formed of ceramics. The ceramics may contain alumina (Al₂O₃) as a major component, may contain a trace amount of silica (SiO₂) to promote sintering of the ceramics, and may contain an additive containing an Mn element. Another component may also be contained. A material for the ceramic insulating layer 24 may be mixed powder of Al₂O₃ powder of 50 wt % or more as a major component, Si element containing powder of 5 wt % to 17 wt % in terms of SiO₂ equivalent, and Mn element containing powder of 3 wt % to 14 wt % in terms of MnO equivalent, for example. A firing temperature when the mixed powder is used is 1150° C. to 1300° C., for example.

The conductor layer 34 may contain Cu and at least one refractory metal selected from the group consisting of W and Mo. When a total volume of the conductor layer 34 is defined as 100 vol %, the conductor layer 34 may contain ceramics of 30 vol % or less. The ceramics are alumina, for example. Other ceramics may be contained together with or in place of alumina, and SiO₂ and/or MnO₂ may be contained, for example. The conductor layer 34 contains ceramics to improve adhesion between the conductor layer 34 and the ceramic insulating layer 24. The ceramics may contain fine particles of silicon oxide having an average particle size of 5 nm or more and 200 nm or less. The conductor layer 34 and the heat dissipating plate 11 described above may be formed of a common material. They, however, may be formed of different materials for any reason.

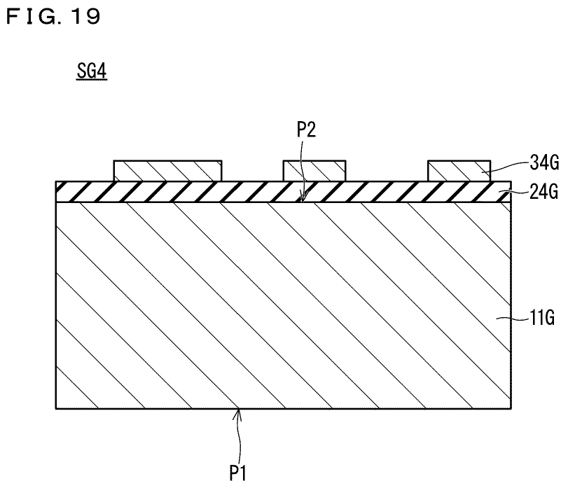

FIG. 19 is a schematic partial cross-sectional view showing one step of a method of manufacturing the heat dissipating substrate 54. In the step, a laminated body SG4 including the laminated body 11G is formed in place of the laminated body SG (FIG. 6: Embodiment 1) including the laminated body 11G. As in a case of Embodiment 1, a single green sheet may be used in place of the laminated body 11G. The laminated body SG4 further includes a green sheet 24G to be the ceramic insulating layer 24 by being fired. A ceramic paste layer to be the ceramic insulating layer by being fired may be formed by printing instead of laminating the green sheet 24G on the laminated body 11G. The laminated body SG4 further includes a green sheet 34G to be the conductor layer 34 by being fired. A conductor paste layer to be the conductor layer 34 by being fired may be formed by printing in place of the green sheet 34G. The heat dissipating substrate 54 is obtained by firing the laminated body SG4.

A configuration other than the above-mentioned configuration is substantially the same as the above-mentioned configuration according to Embodiment 1, so that the same or corresponding elements bear the same reference signs, and description thereof is not repeated.

### EXAMPLES AND COMPARATIVE EXAMPLES

A single heat dissipating member like the heat dissipating plate 11 according to Embodiment 3 was manufactured and evaluated. First, a raw material composition, that is, a composition of mixed powder, a raw material particle size, and a Cu introduction method are shown in Table 1 below.

TABLE 1

| | RAW MATERIAL COMPOSITION [wt %] | | | | RAW MATERIAL | | Cu |
|---|---|---|---|---|---|---|---|
| | SUBTOTAL 100 wt % | | | | PARTICLE SIZE [μm] | | INTRODUCTION |
| | Cu | W | Mo | SiO₂ | W, Mo | SiO₂ | METHOD |
| COMPARATIVE EXAMPLE 1 | 11.0 | 89.0 | 0.0 | 0.0 | 1.5 | — | IMPREGNATION |
| COMPARATIVE EXAMPLE 2 | 20.0 | 80.0 | 0.0 | 0.0 | 1.5 | — | IMPREGNATION |
| COMPARATIVE EXAMPLE 3 | 30.0 | 0.0 | 70.0 | 0.0 | 1.5 | — | IMPREGNATION |
| COMPARATIVE EXAMPLE 4 | 60.0 | 0.0 | 40.0 | 0.0 | 1.5 | — | IMPREGNATION |
| COMPARATIVE EXAMPLE 5 | 30.0 | 0.0 | 70.0 | 0.1 | 1.5 | 1.5 | POWDER MIXING |
| EXAMPLE 1 | 7.5 | 92.5 | 0.0 | 0.1 | 0.8 | 0.017 | POWDER MIXING |
| EXAMPLE 2 | 16.5 | 83.5 | 0.0 | 0.5 | 0.8 | 0.017 | POWDER MIXING |
| EXAMPLE 3 | 27.4 | 72.6 | 0.0 | 0.8 | 0.8 | 0.017 | POWDER MIXING |
| EXAMPLE 4 | 31.6 | 68.4 | 0.0 | 0.1 | 0.8 | 0.017 | POWDER MIXING |
| EXAMPLE 5 | 31.6 | 68.4 | 0.0 | 0.5 | 0.8 | 0.017 | POWDER MIXING |
| EXAMPLE 6 | 31.6 | 68.4 | 0.0 | 1.0 | 0.8 | 0.017 | POWDER MIXING |
| EXAMPLE 7 | 31.6 | 68.4 | 0.0 | 2.0 | 0.8 | 0.017 | POWDER MIXING |
| EXAMPLE 8 | 31.6 | 68.4 | 0.0 | 3.0 | 0.8 | 0.017 | POWDER MIXING |
| COMPARATIVE EXAMPLE 6 | 31.6 | 68.4 | 0.0 | 4.0 | 0.8 | 0.017 | POWDER MIXING |
| EXAMPLE 9 | 41.0 | 59.0 | 0.0 | 1.2 | 0.8 | 0.017 | POWDER MIXING |
| EXAMPLE 10 | 64.8 | 35.2 | 0.0 | 1.9 | 0.8 | 0.017 | POWDER MIXING |
| EXAMPLE 11 | 80.6 | 19.4 | 0.0 | 2.4 | 0.8 | 0.017 | POWDER MIXING |
| EXAMPLE 12 | 13.3 | 0.0 | 86.7 | 0.5 | 1.5 | 0.017 | POWDER MIXING |
| EXAMPLE 13 | 46.5 | 0.0 | 53.5 | 1.0 | 1.5 | 0.017 | POWDER MIXING |
| EXAMPLE 14 | 88.7 | 0.0 | 11.3 | 1.0 | 1.5 | 0.017 | POWDER MIXING |

Amorphous silicon oxide was used as silicon oxide. In a column “Cu INTRODUCTION METHOD” in Table 1 above, “IMPREGNATION” indicates that Cu was introduced into a W or Mo porous body by impregnation. “POWDER MIXING” indicates that Cu powder was mixed in a powder mixing step of preparing powder to be fired. A firing temperature during firing was 1250° C.

While a composition of the heat dissipating member is expressed relative to the total weight of Cu, W, and Mo in Table 1 above, it is converted to be expressed relative to a total weight of Cu, W, Mo, and silicon oxide (SiO₂) as shown in Table 2 below.

TABLE 2

| | RAW MATERIAL COMPOSITION (wt %) | | | |
|---|---|---|---|---|
| | SUBTOTAL 100 wt % | | | |
| | Cu | W | Mo | SiO₂ |
| COMPARATIVE | 11.0 | 89.0 | 0.0 | 0.0 |
| EXAMPLE 1 | | | | |
| COMPARATIVE | 20.0 | 80.0 | 0.0 | 0.0 |
| EXAMPLE 2 | | | | |
| COMPARATIVE | 30.0 | 0.0 | 70.0 | 0.0 |
| EXAMPLE 3 | | | | |
| COMPARATIVE | 60.0 | 0.0 | 40.0 | 0.0 |
| EXAMPLE 4 | | | | |
| COMPARATIVE | 30.0 | 0.0 | 69.9 | 0.1 |
| EXAMPLE 5 | | | | |
| EXAMPLE 1 | 7.5 | 92.4 | 0.0 | 0.1 |
| EXAMPLE 2 | 16.4 | 83.1 | 0.0 | 0.5 |
| EXAMPLE 3 | 27.2 | 72.0 | 0.0 | 0.8 |
| EXAMPLE 4 | 31.5 | 68.4 | 0.0 | 0.1 |
| EXAMPLE 5 | 31.4 | 68.1 | 0.0 | 0.5 |
| EXAMPLE 6 | 31.2 | 67.8 | 0.0 | 1.0 |
| EXAMPLE 7 | 30.9 | 67.1 | 0.0 | 2.0 |
| EXAMPLE 8 | 30.6 | 66.4 | 0.0 | 2.9 |
| COMPARATIVE | 30.3 | 65.8 | 0.0 | 3.8 |
| EXAMPLE 6 | | | | |
| EXAMPLE 9 | 40.5 | 58.3 | 0.0 | 1.2 |
| EXAMPLE 10 | 63.6 | 34.5 | 0.0 | 1.9 |
| EXAMPLE 11 | 78.7 | 18.9 | 0.0 | 2.4 |
| EXAMPLE 12 | 13.2 | 0.0 | 86.3 | 0.5 |
| EXAMPLE 13 | 46.0 | 0.0 | 53.0 | 1.0 |
| EXAMPLE 14 | 87.8 | 0.0 | 11.2 | 1.0 |

A composition and a result of evaluation of a heat dissipating member obtained using the above-mentioned raw materials are shown in Table 3 below.

TABLE 3

| | COMPOSITION AFTER FIRING [wt %] | | | | | | | COEFFICIENT | STRESS AT |
|---|---|---|---|---|---|---|---|---|---|
| | | | | | SILICON OXIDE PARTICLE | | | OF THERMAL | STRAIN OF |
| | SUBTOTAL 100 wt % | | | | SIZE DISTRIBUTION [μm] | | SINTERED | EXPANSION | 1% |
| | Cu | W | Mo | SiO₂ | 0.2-1.0 | 1.0-2.0 | STATE | [ppm/K] | [MPa] |
| COMPARATIVE | 11.0 | 89.0 | 0.0 | 0.00 | — | — | SUFFICIENT | 6.5 | 65 |
| EXAMPLE 1 | | | | | | | | | |
| COMPARATIVE | 20.0 | 80.0 | 0.0 | 0.00 | — | — | SUFFICIENT | 7.9 | 77 |
| EXAMPLE 2 | | | | | | | | | |
| COMPARATIVE | 30.0 | 0.0 | 70.0 | 0.00 | — | — | SUFFICIENT | 7.7 | 67 |
| EXAMPLE 3 | | | | | | | | | |
| COMPARATIVE | 60.0 | 0.0 | 40.0 | 0.00 | — | — | SUFFICIENT | 11.5 | 46 |
| EXAMPLE 4 | | | | | | | | | |
| COMPARATIVE | 30.0 | 0.0 | 70.0 | 0.10 | 10% | 90% | INSUFFICIENT | — | — |
| EXAMPLE 5 | | | | | | | | | |
| EXAMPLE 1 | 7.5 | 92.5 | 0.0 | 0.03 | 70% | 30% | SUFFICIENT | 6.9 | 40 |
| EXAMPLE 2 | 16.5 | 83.5 | 0.0 | 0.17 | 79% | 21% | SUFFICIENT | 9.1 | 35 |
| EXAMPLE 3 | 27.4 | 72.6 | 0.0 | 0.28 | 77% | 23% | SUFFICIENT | 11.3 | 32 |
| EXAMPLE 4 | 31.6 | 68.4 | 0.0 | 0.03 | 72% | 28% | SUFFICIENT | 12.1 | 32 |
| EXAMPLE 5 | 31.6 | 68.4 | 0.0 | 0.17 | 81% | 19% | SUFFICIENT | 12.1 | 31 |
| EXAMPLE 6 | 31.6 | 68.4 | 0.0 | 0.34 | 85% | 15% | SUFFICIENT | 12.0 | 30 |
| EXAMPLE 7 | 31.6 | 68.4 | 0.0 | 0.68 | 88% | 12% | SUFFICIENT | 11.8 | 30 |
| EXAMPLE 8 | 31.6 | 68.4 | 0.0 | 1.01 | 89% | 11% | SUFFICIENT | 11.5 | 29 |
| COMPARATIVE | 31.6 | 68.4 | 0.0 | 1.34 | 89% | 11% | INSUFFICIENT | — | — |
| EXAMPLE 6 | | | | | | | | | |
| EXAMPLE 9 | 41.0 | 59.0 | 0.0 | 0.42 | 80% | 20% | SUFFICIENT | 13.3 | 23 |
| EXAMPLE 10 | 64.8 | 35.2 | 0.0 | 0.66 | 85% | 15% | SUFFICIENT | 16.5 | 15 |
| EXAMPLE 11 | 80.6 | 19.4 | 0.0 | 0.82 | 88% | 12% | SUFFICIENT | 17.5 | 13 |
| EXAMPLE 12 | 13.3 | 0.0 | 86.7 | 1.29 | 81% | 19% | SUFFICIENT | 7.8 | 40 |
| EXAMPLE 13 | 46.5 | 0.0 | 53.5 | 0.73 | 86% | 14% | SUFFICIENT | 12.6 | 23 |
| EXAMPLE 14 | 88.7 | 0.0 | 11.3 | 0.38 | 86% | 14% | SUFFICIENT | 18.0 | 15 |

According to the inventor's preliminary study, a change in composition of the heat dissipating member from the raw material composition (composition of the mixed powder) to a composition after firing (composition of the heat dissipating member) was sufficiently small for Cu, W, and Mo. Values of the raw material composition shown in Table 1 were thus used for these elements. On the other hand, a silicon oxide content in a cross section of the heat dissipating member estimated from an electron micrograph at 2000× magnification descried above was significantly reduced from a silicon oxide content in the mixed powder. A reflection electron image at 25000× magnification was checked just to be sure, but silicon oxide particles other than silicon oxide particles recognized in the above-mentioned electron micrograph were not observed. Si elements were not significantly detected in qualitative analysis using an electron probe micro analyzer (EPMA) for a region in which the silicon oxide particles were not observed. Silicon oxide is thus considered to be emitted from the heat dissipating member during firing. A silicon oxide content after firing was thus calculated using the image data of the electron micrograph as described above. The content is expressed in terms of SiO₂ equivalent.

Referring to Table 3, in Comparative Example 5, a sintered state was insufficient, that is, the sintered body was not dense, and there were many pores in the sintered body. This is considered to be related to raw material particle sizes of SiO₂ powder mixed during manufacture. Although a specific reason is unknown, such a phenomenon is noticeable when SiO₂ powder has a particle size of more than 200 nm. Although not shown in Table 3, similar results were seen when Mo in Comparative Example 5 was replaced with W.

In each of Comparative Examples 1 to 4, impregnation was used to introduce Cu elements in contrast to the present embodiment.

“SILICON OXIDE PARTICLE SIZE DISTRIBUTION” means particle size distribution based on the number of particles based on electron microscopy of the silicon oxide particles. Specifically, “0.2-1.0” indicates a percentage of a particle size range of 0.2 μm or more and less than 1.0 μm, and “1.0-2.0” indicates a percentage of a particle size range of 1.0 μm or more and less than 2.0 μm. Results show that, in particle size distribution based on the number of particles in a particle size range of 0.2 μm or more and less than 2.0 μm, a percentage of a particle size range of 0.2 μm or more and less than 1.0 μm was 70% or more in each of Examples. Complementing the inventor's study, in particle size distribution based on the number of particles in a particle size range of 0.2 μm or more and less than 3.0 μm, a percentage of a particle size range of 0.2 μm or more and less than 1.0 μm was 70% or more in each of Examples. Further complementing the study, in particle size distribution based on the number of particles in a particle size range of 0.2 μm or more and less than 5.0 μm, a percentage of a particle size range of 0.2 μm or more and less than 1.0 μm was 70% or more in each of Examples. Further complementing the study, in particle size distribution based on the number of particles in a particle size range of 0.2 μm or more and less than 10 μm, a percentage of a particle size range of 0.2 μm or more and less than 1.0 μm was 70% or more in each of Examples.

In each of Examples, the silicon oxide particles of the heat dissipating member each had a particle size of less than 10 μm. The number of silicon oxide particles each having a particle size of 10 μm or more is preferably small and is more preferably substantially zero. This can further diminish the concern that breakage of the heat dissipating plate 11 originates from the silicon oxide particles. Complementing the inventor's study, the silicon oxide particles of the heat dissipating member each had a particle size of less than 5.0 μm in each of Examples. The number of silicon oxide particles each having a particle size of 5.0 μm or more is preferably small and is more preferably substantially zero. This can further diminish the concern that breakage of the heat dissipating plate 11 originates from the silicon oxide particles. Further complementing the study, the silicon oxide particles of the heat dissipating member each had a particle size of less than 3.0 μm in each of Examples. The number of silicon oxide particles each having a particle size of 3.0 μm or more is preferably small and is more preferably substantially zero. This can further diminish the concern that breakage of the heat dissipating plate 11 originates from the silicon oxide particles. Further complementing the study, the silicon oxide particles of the heat dissipating member each had a particle size of less than 2.0 μm in each of Examples. The number of silicon oxide particles each having a particle size of 2.0 μm or more is preferably small and is more preferably substantially zero. This can further diminish the concern that breakage of the heat dissipating plate 11 originates from the silicon oxide particles.

In Table 3 above, a column “SINTERED STATE” indicates a result of evaluation on whether a sintered state withstanding use as the heat dissipating member was obtained. “COEFFICIENT OF THERMAL EXPANSION” was calculated based on thermal expansion between a room temperature and 100° C. A stress value at a bending strain of 1% was measured as an indicator of the Young's modulus. It follows that the lower the stress value, the lower the Young's modulus. A value of the bending strain was measured by a method using a strain gauge in three-point bending in JISR 1602.

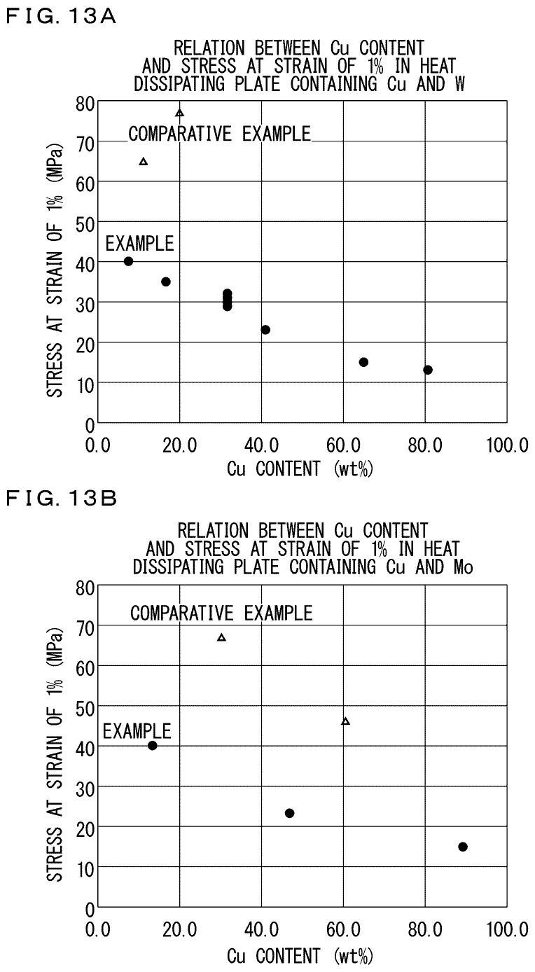

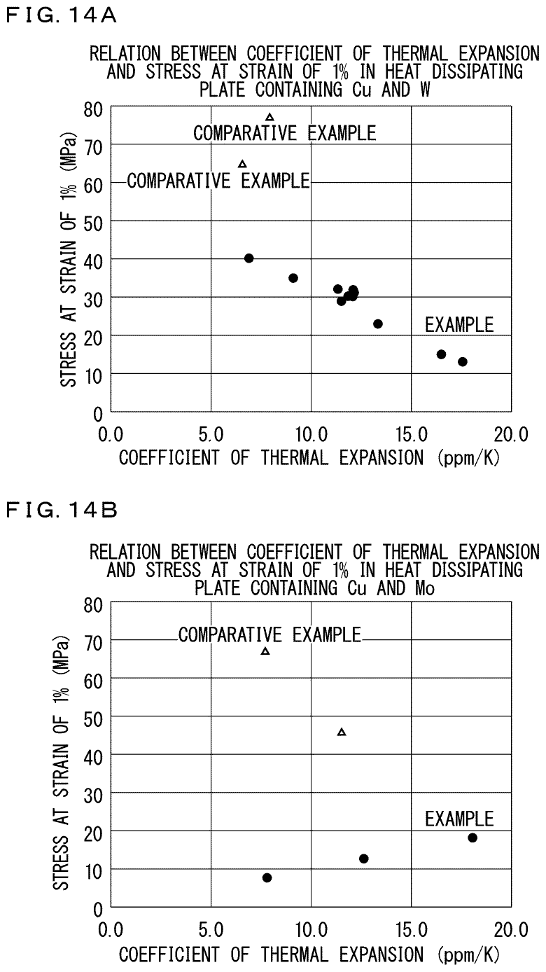

FIGS. 10, 11, and 12 are electron micrographs of cross sections of heat dissipating members in Example 2, Example 3, and Example 9, respectively. In each of these micrographs, a white portion is tungsten, a gray portion is copper, and a black portion is the silicon oxide particles. Silicon oxide in each of Examples 1 to 14 was amorphous silicon oxide. FIGS. 13A and 13B are graphs each showing a relation between a Cu content and stress at a strain of 1%. In each of the heat dissipating plate containing Cu and W shown in FIG. 13A and the heat dissipating plate containing Cu and Mo shown in FIG. 13B, stress at a strain of 1% was lower in each of Examples (filled circle markers) than that in each of Comparative Examples (triangle markers). FIGS. 14A and 14B are graphs each showing a relation between a coefficient of thermal expansion and stress at a strain of 1%. For example, when pieces of data at the same coefficient of thermal expansion were compared, a stress value was smaller in each of Examples (filled circle markers) than that in each of Comparative Examples (triangle markers).

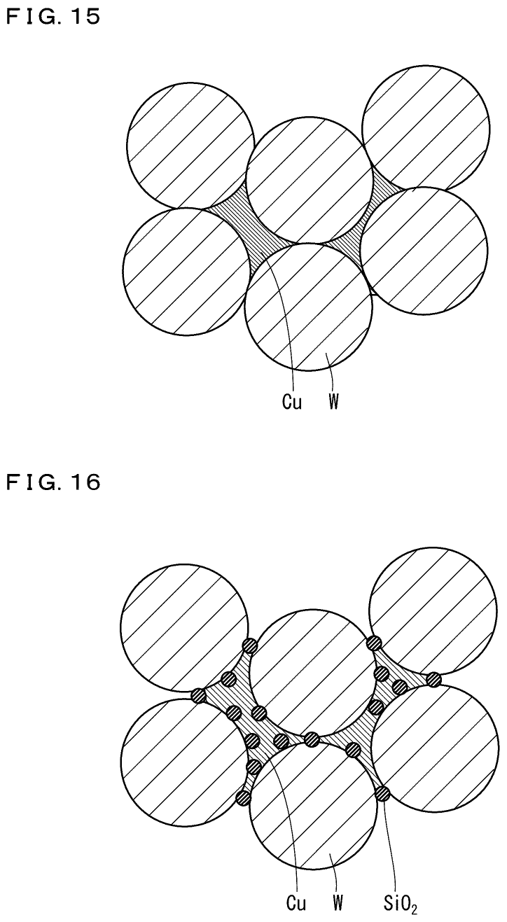

FIG. 15 is a diagram schematically showing a fine structure of a heat dissipating member which contains Cu and W and in which silicon oxide particles are not dispersed. In this structure, Cu has infiltrated the void space among mutually sintered W particles. In this case, W particles having high Young's moduli are likely to be directly bonded to each other. As a result, the heat dissipating member has a high Young's modulus. In contrast, FIG. 16 is a diagram schematically showing a fine structure of a heat dissipating member which contains Cu and W and in which silicon oxide particles are dispersed. In this structure, fine silicon oxide particles are located among W particles to interfere with direct bonding of the W particles having high Young's moduli, and Cu having a low Young's modulus is likely to infiltrate among W particles. As a result, the Young's modulus of the heat dissipating member is suppressed. While this effect produced by the silicon oxide particles is sufficiently achieved, a silicon oxide content can be suppressed to the extent that the silicon oxide particles do not have a large negative impact on thermal conductivity of the heat dissipating member because the silicon oxide particles are fine particles. The same applies to a case where Mo particles are used in place of W particles in FIGS. 15 and 16.

While the composition of the heat dissipating member is expressed relative to the total weight of Cu, W, and Mo in Table 3 above, it is converted to be expressed relative to the total weight of Cu, W, Mo, and silicon oxide (SiO₂) as shown in Table 4 below.

TABLE 4

| | COMPOSITION AFTER FIRING [wt %] | | | |
|---|---|---|---|---|
| | SUBTOTAL 100 wt % | | | |
| | Cu | W | Mo | SiO₂ |
| COMPARATIVE | 11.0 | 89.0 | 0.0 | 0.0 |
| EXAMPLE 1 | | | | |
| COMPARATIVE | 20.0 | 80.0 | 0.0 | 0.0 |
| EXAMPLE 2 | | | | |
| COMPARATIVE | 30.0 | 0.0 | 70.0 | 0.0 |
| EXAMPLE 3 | | | | |
| COMPARATIVE | 60.0 | 0.0 | 40.0 | 0.0 |
| EXAMPLE 4 | | | | |
| COMPARATIVE | 30.0 | 0.0 | 69.9 | 0.1 |
| EXAMPLE 5 | | | | |
| EXAMPLE 1 | 7.5 | 92.5 | 0.0 | 0.0 |
| EXAMPLE 2 | 16.5 | 83.4 | 0.0 | 0.2 |
| EXAMPLE 3 | 27.3 | 72.4 | 0.0 | 0.3 |
| EXAMPLE 4 | 31.5 | 68.4 | 0.0 | 0.0 |
| EXAMPLE 5 | 31.5 | 68.3 | 0.0 | 0.2 |
| EXAMPLE 6 | 31.5 | 68.2 | 0.0 | 0.3 |
| EXAMPLE 7 | 31.3 | 68.0 | 0.0 | 0.7 |
| EXAMPLE 8 | 31.2 | 67.8 | 0.0 | 1.0 |
| COMPARATIVE | 31.1 | 67.5 | 0.0 | 1.3 |
| EXAMPLE 6 | | | | |
| EXAMPLE 9 | 40.8 | 58.8 | 0.0 | 0.4 |
| EXAMPLE 10 | 64.4 | 34.9 | 0.0 | 0.7 |
| EXAMPLE 11 | 79.9 | 19.2 | 0.0 | 0.8 |
| EXAMPLE 12 | 13.3 | 0.0 | 85.6 | 0.2 |
| EXAMPLE 13 | 46.3 | 0.0 | 53.1 | 0.3 |
| EXAMPLE 14 | 88.4 | 0.0 | 11.3 | 0.3 |

What is claimed is:

1. A heat dissipating member comprising:
a sintered material portion containing copper and at least one of tungsten and molybdenum; and
a plurality of silicon oxide particles dispersed in the sintered material portion, wherein
the heat dissipating member has a copper content of M_{Cu} weight percent, a tungsten content of M_{W} weight percent, a molybdenum content of M_{Mo} weight percent, and a silicon oxide content of M_{SiO2} weight percent in terms of SiO₂ equivalent, relative to a total weight of copper, tungsten, and molybdenum, the heat dissipating member satisfying
$$0.9 \geq {M}_{Cu} ( {M}_{Cu} + {M}_{W} + {M}_{Mo} ) \geq 0.045 , and$$
$$0.01 \geq {M}_{SiO 2} / ( {M}_{Cu} + {M}_{W} + {M}_{Mo} ) \geq 0 \text{.0003} .$$

2. The heat dissipating member according to claim 1, wherein
in particle size distribution based on the number of particles in a particle size range of the plurality of silicon oxide particles of 0.2 μm or more and less than 10 μm, a percentage of a particle size range of 0.2 μm or more and less than 1.0 μm is 70% or more.

3. The heat dissipating member according to claim 2, wherein
the plurality of silicon oxide particles each have a particle size of less than 10 μm.

4. The heat dissipating member according to claim 1, wherein
in particle size distribution based on the number of particles in a particle size range of the plurality of silicon oxide particles of 0.2 μm or more and less than 5 μm, a percentage of a particle size range of 0.2 μm or more and less than 1.0 μm is 70% or more.

5. The heat dissipating member according to claim 4, wherein
the plurality of silicon oxide particles each have a particle size of less than 5 μm.

6. The heat dissipating member according to claim 1, wherein
in particle size distribution based on the number of particles in a particle size range of the plurality of silicon oxide particles of 0.2 μm or more and less than 3 μm, a percentage of a particle size range of 0.2 μm or more and less than 1.0 μm is 70% or more.

7. The heat dissipating member according to claim 6, wherein
the plurality of silicon oxide particles each have a particle size of less than 3 μm.

8. The heat dissipating member according to claim 1, wherein
in particle size distribution based on the number of particles in a particle size range of the plurality of silicon oxide particles of 0.2 μm or more and less than 2 μm, a percentage of a particle size range of 0.2 μm or more and less than 1.0 μm is 70% or more.

9. The heat dissipating member according to claim 8, wherein
the plurality of silicon oxide particles each have a particle size of less than 2 μm.

10. The heat dissipating member according to claim 1, the heat dissipating member satisfying
$$0.8 \geq {M}_{Cu} / ( {M}_{Cu} + {M}_{W} + {M}_{Mo} ) \geq 0.15 .$$

11. The heat dissipating member according to claim 1, wherein
a remainder of the heat dissipating member other than copper, tungsten, molybdenum, and silicon oxide accounts for less than 0.5 weight percent relative to the total weight.

12. The heat dissipating member according to claim 1, the heat dissipating member satisfying:
$${M}_{Mo} = 0 ; and$$
$$0.806 \geq {M}_{Cu} / ( {M}_{Cu} + {M}_{W} ) \geq 0.075 .$$

13. The heat dissipating member according to claim 1, the heat dissipating member satisfying:
$${M}_{W} = 0 ; and$$
$$0.887 \geq {M}_{Cu} / ( {M}_{Cu} + {M}_{Mo} ) \geq 0.133 .$$

14. A heat dissipating member manufacturing method for manufacturing the heat dissipating member according to claim 1, the heat dissipating member manufacturing method comprising:
mixing at least one of tungsten powder having an average particle size of 0.5 μm or more and 10 μm or less and molybdenum powder having an average particle size of 0.5 μm or more and 10 μm or less, copper powder having an average particle size of 1.5 μm or more and 5.0 μm or less, and SiO₂ powder having an average particle size of 7 nm or more and 200 nm or less to form mixed powder, the mixed powder having a copper content of M_{Cu(P)} weight percent, a tungsten content of M_{W(P)} weight percent, a molybdenum content of M_{Mo(P)} weight percent, and a silicon oxide content of M_{SiO2(P)} weight percent in terms of SiO₂ equivalent, relative to a total weight of copper, tungsten, and molybdenum, the mixed powder satisfying
$$0.9 \geq {M}_{Cu ( P )} / ( {M}_{Cu ( P )} + {M}_{W ( P )} + {M}_{Mo ( P )} ) \geq 0.045 , and$$
$$0.03 \geq {M}_{SiO 2 ( P )} / ( {M}_{Cu ( P )} + {M}_{W ( P )} + {M}_{Mo ( P )} ) \geq 0.0 \; 01 ; and$$
heating the mixed powder to a temperature at or above a melting point of copper.

15. The heat dissipating member manufacturing method according to claim 14, further comprising
forming at least one green sheet containing the mixed powder and a resin, wherein
the heating of the mixed powder is performed by firing the at least one green sheet.

16. The heat dissipating member manufacturing method according to claim 15, wherein the at least one green sheet including a plurality of green sheets, the manufacturing method further comprising
laminating the plurality of green sheets to form a laminated body, wherein
the heating of the mixed powder is performed by firing the laminated body.

17. A package comprising:
the heat dissipating member according to claim 1; and
a ceramic frame, wherein
the heat dissipating member has a heat dissipating surface and a main surface opposite the heat dissipating surface, and
the ceramic frame is disposed on the main surface of the heat dissipating member and has an inner surface surrounding a cavity and an outer surface opposite the inner surface.

18. A substrate comprising:
the heat dissipating member according to claim 1; and
a ceramic insulating layer, wherein
the heat dissipating member has a heat dissipating surface and a main surface opposite the heat dissipating surface, and
the ceramic insulating layer is disposed on the main surface of the heat dissipating member.
